(19) United States
(12) Patent Application Publication
(10) Pub. No.: US 2026/0198132 A1
(43) Pub. Date: Jul. 9, 2026

(54) DISPLAY PANEL

(71) Applicant: GIANTPLUS TECHNOLOGY CO., LTD., Miauli County (TW)

(72) Inventors: I-Ta JIANG, Miauli County (TW); Che-Yao WU, Miauli County (TW); Kai-Ju CHOU, Miauli County (TW)

(73) Assignee: GIANTPLUS TECHNOLOGY CO., LTD., Miauli County (TW)

(21) Appl. No.: 19/278,814

(22) Filed: Jul. 24, 2025

(30) Foreign Application Priority Data
Jan. 8, 2025 (TW) 114200282

(51) Int. Cl. H10F 77/00; G02F 1/1333; G02F 1/1339; H10F 19/90

(52) U.S. Cl. CPC H10F 77/935; H10F 19/90; G02F 1/133388; G02F 1/1339

(57) ABSTRACT

A display panel includes an array substrate, a sealant layer and an optical substrate. The sealant layer is disposed on the array substrate and located on the first bezel area. The optical substrate is disposed on the sealant layer and comprises a solar conversion layer, an electrode conductive layer, a patterned organic layer and an upper electrode layer. The patterned organic layer is disposed on the electrode conductive layer and exposes a portion of the electrode conductive layer. Due to the configuration of the patterned organic layer, the sealant layer of the display panel is not affected by the structure of a solar cell unit and has the same thickness and height. Therefore, the display area of the display panel has a uniform display effect.

### CROSS REFERENCE TO RELATED APPLICATION

This application claims the priority benefit of Taiwan Patent Application Serial Number 114200282, filed on Jan. 8, 2025, the full disclosure of which is incorporated herein by reference.

### BACKGROUND

### Technical Field

The present disclosure is related to a display device, and more particularly to a display panel which may execute a photoelectric converter through an optical substrate.

### Related Art

In order to meet needs of daily life or work, it has become a trend to carry electronic products with a display panel. When the electronic products need to operate for a long time, the power consumption of the electronic products also increases. In addition to carrying a power bank to charge the electronic products, a new charging method is to charge the electronic products with solar energy.

In order to effectively utilize solar energy and achieve the purpose of making a display panel thinner and lighter, a display panel that combines an optical substrate (e.g. a color filter substrate) with a solar cell has been proposed. By integrating solar cells into an optical substrate, the number of glass substrates in a display panel is effectively reduced. Thereby, the overall thickness of the display panel is significantly reduced.

Generally, in order to match the structure of the solar cell and avoid failure of the solar cell due to an unintended electrical connection, the optical substrate located on upper and lower bezel areas of the display panel may be isolated from the solar cell by setting an insulating layer such that sealant components located on the upper and lower bezel areas are isolated from the solar cell by the insulating layer. However, this causes gaps between left and right bezel areas of the display panel to be larger than gaps between upper and lower bezel areas and results in uneven display effects on the existing display panel. Therefore, existing devices and systems have considerable requirements for a display panel with a uniform display effect.

### SUMMARY

The embodiment of the present disclosure is related to a display panel configured with a patterned organic layer such that a sealant layer of the display panel is not affected by a structure of a solar cell unit and has the same thickness and height. Thus, a display area of the display panel has a uniform display effect.

In order to achieve the above object and other related objects, the present disclosure is related to a display panel. The display panel includes a display area and a bezel area surrounding the display area. The bezel area includes a plurality of first bezel areas and a plurality of second bezel areas. The second bezel areas are extended along a first axis, the first bezel areas are extended along a second axis, and the first axis is perpendicular to the second axis. The display panel further comprises an array substrate, a sealant layer and an optical substrate. The sealant layer is disposed on the array substrate, located on the first bezel area and electrically connected to the array substrate. The optical substrate is disposed on the sealant layer and electrically connected to the sealant layer. The optical substrate includes a solar conversion layer, an electrode conductive layer, a patterned organic layer and an upper electrode layer. The electrode conductive layer is disposed on the solar conversion layer and electrically connected to the solar conversion layer and the sealant layer. The patterned organic layer is disposed on the electrode conductive layer and exposes a portion of the electrode conductive layer. The upper electrode layer is disposed on the patterned organic layer, located between the patterned organic layer and the sealant layer and electrically connected to the electrode conductive layer exposed by the patterned organic layer and the sealant layer.

According to the above, the sealant layer of the display panel is not affected by the structure of a solar cell unit and has the same thickness and height by the configuration of the patterned organic layer, and the electrical connection between the electrode conductive layer, the sealant layer and the array substrate is maintained. Therefore, the solar cell may operate normally and the display area of the display panel has a uniform display effect.

It should be understood, however, that this summary may not contain all aspects and embodiments of the present invention, that this summary is not meant to be limiting or restrictive in any manner, and that the invention as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows in conjunction with the accompanying drawings, in which:

FIG. 1 is a schematic of a top view of a display panel according to an embodiment of the present disclosure.

FIG. 2 is a schematic of an AA′ section line of FIG. 1 according to an embodiment of the present disclosure.

FIG. 3 is a schematic of a BB′ section ling of FIG. 1 according to an embodiment of the present disclosure.

FIG. 4 is a schematic of a pattern unit of a patterned organic layer under a unit area according to an embodiment of the present disclosure.

FIG. 5 is a schematic of a pattern unit of a patterned organic layer under a unit area according to an embodiment of the present disclosure.

FIG. 6 is a schematic of a pattern unit of a patterned organic layer under a unit area according to an embodiment of the present disclosure.

### DETAILED DESCRIPTION OF THE EMBODIMENTS

The present invention will be described more fully hereinafter with reference to the accompanying drawings, in which exemplary embodiments of the invention are shown. This present invention may, however, be embodied in many different forms and should not be construed as limited to the embodiments set forth herein. Rather, these embodiments are provided so that the description of the present invention will be thorough and complete and will fully convey the scope of the present invention to those skilled in the art.

Certain terms are used throughout the description and following claims to refer to particular components. As one skilled in the art will appreciate, manufacturers may refer to a component by different names. This document does not intend to distinguish between components that differ in name but not in function. In the following description and in the claims, the terms “include/including” and “comprise/comprising” are used in an open-ended fashion and thus should be interpreted as “including but not limited to”. “Substantial/substantially” means, within an acceptable error range, a person skilled in the art may solve the technical problem in a certain error range to achieve the basic technical effect.

The following description is of the best-contemplated mode of carrying out the invention. This description is provided for the purpose of illustration of the general principles of the invention and should not be taken in a limiting sense. The scope of the invention is best determined by reference to the appended claims.

Moreover, the terms “include”, “contain”, and any variation thereof are intended to cover a non-exclusive inclusion. Therefore, a process, method, object, or device that comprises a series of elements not only includes these elements but also comprises other elements not specified expressly, or may include inherent elements of the process, method, object, or device. If no more limitations are made, an element limited by “include a/an . . . ” does not exclude other same elements existing in the process, the method, the article, or the device which comprises the element.

In the following embodiment, the same reference numerals are used to refer to the same or similar elements throughout the invention.

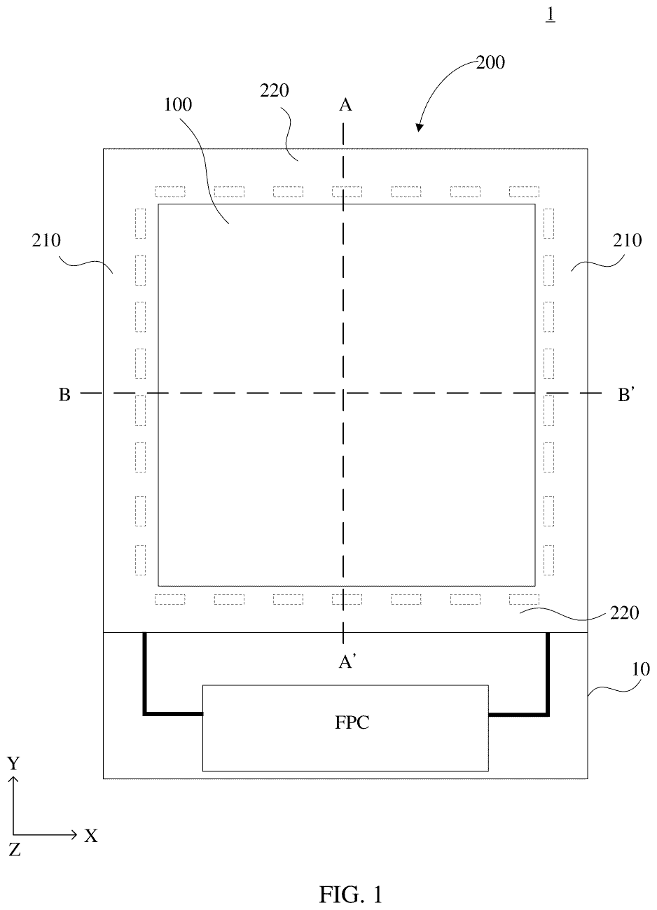

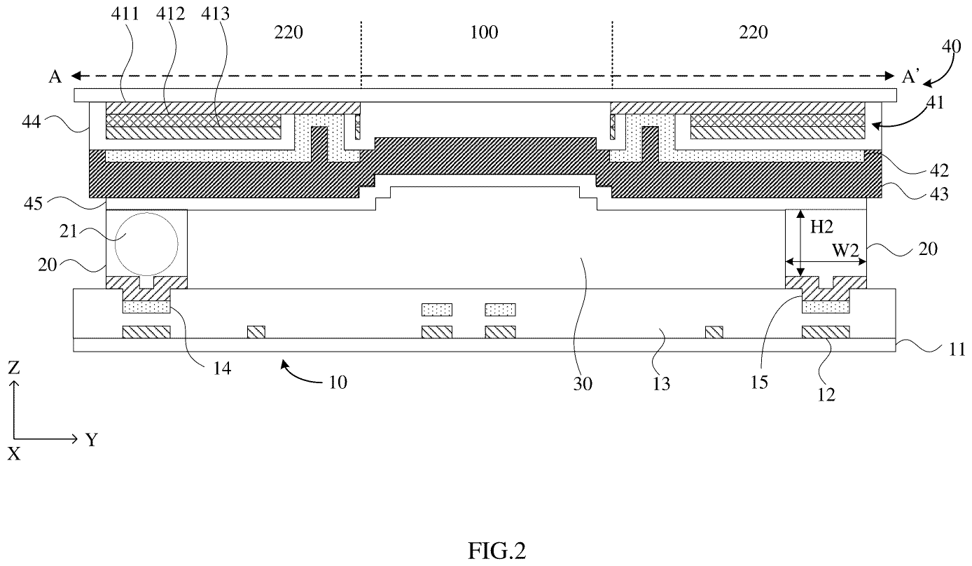

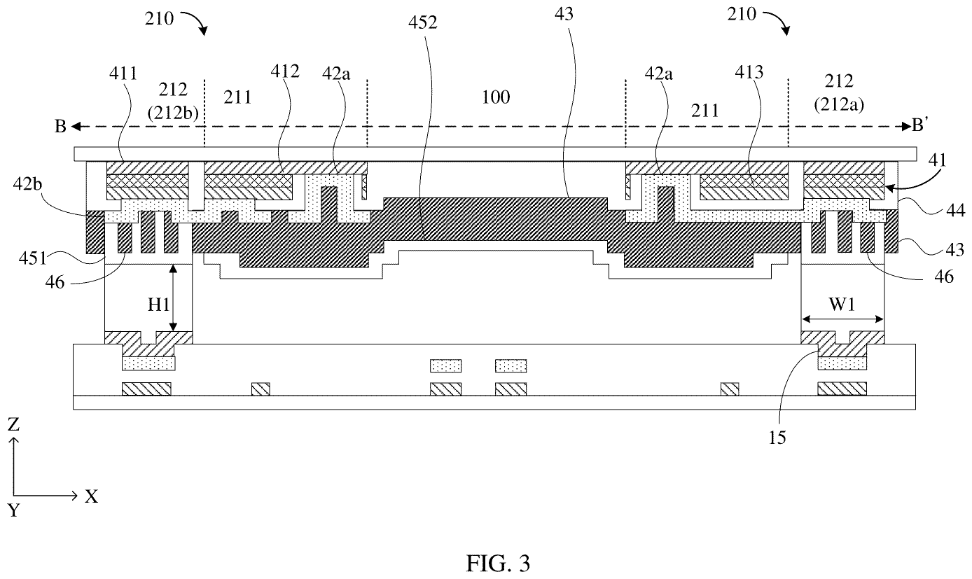

Please refer to FIG. 1 to FIG. 3. FIG. 1 is a schematic of a top view of a display panel 1. FIG. 2 is a schematic of an AA′ section line of FIG. 1. FIG. 3 is a schematic of a BB′ section line of FIG. 1. The display panel 1 includes a display area 100 and a bezel area 200 disposed around the display area 100. The display area 100 is used to display a display image. The bezel area 200 includes a plurality of first bezel areas 210 and a plurality of second bezel areas 220. The second bezel area 220 extends along a first axis X. The first bezel area 210 extends along a second axis Y. The first axis X is perpendicular to the second axis Y. The bezel area 200 is used to dispose a plurality of solar cell units and as a wiring area for electronic components.

Please refer to FIG. 2. The display panel 1 includes an array substrate 10, a sealant layer 20, a display medium layer 30 and an optical substrate 40. The array substrate 10, the sealant layer 20, the display medium layer 30, and the optical substrate 40 are stacked on each other along a third axis Z. The third axis Z is perpendicular to the first axis X and the second axis Y. The array substrate 10 includes a substrate 11, an insulating layer 13, conductive layers 12, 14, and a lower electrode 15. The substrate 11 is, for example, a glass substrate. The conductive layer 12 is disposed on the substrate 11. The conductive layer 12 is electrically connected to external circuits through wiring and electrically connected to electronic components in the array substrate 10. For example, the conductive layer 12 is electrically connected to a flexible printed circuit board FPC to transmit gate driving signals from the flexible printed circuit board FPC to corresponding array transistors. The conductive layer 12 is, for example, a metal thin film layer. The conductive layer 14 is disposed on the insulating layer 13. The conductive layer 14 is electrically connected to external circuits through wiring and is electrically connected to electronic components in the array substrate 10. For example, the conductive layer 14 is electrically connected to the flexible printed circuit board FPC to transmit source driving signals from the flexible printed circuit board FPC to corresponding array transistors. The conductive layer 14 is, for example, a metal thin film layer. The insulating layer 13 is disposed on the conductive layer 12 and the conductive layer 14 and at least partially covers the conductive layer 12 and the conductive layer 14. The insulating layer 13 is used to isolate the conductive layers 12 and 14 from other electrical materials to avoid unintended electrical connection paths. The conductive layer 14 located on the second bezel area 220 is exposed by the insulating layer 13. The lower electrode layer 15 is disposed on the conductive layer 14 exposed by the insulating layer 13 and is electrically connected to the conductive layer 14. The lower electrode layer 15 is located on the second bezel area 220. The lower electrode layer is, for example, a transparent conductive film.

In the embodiment, the sealant layer 20 is disposed on the array substrate 10 and is located on the second bezel area 220. The sealant layer 20 is electrically connected to the lower electrode layer 15 of the array substrate. The sealant layer 20 is implemented by, for example, a sealant including conductive balls 21. The sealant layer 20 has a height H2 and a width W2. The height H2 of the sealant layer 20 is determined by a particle size of at least one conductive ball 21. The sealant layer 20 may establish an electrical connection with the array substrate 10 through the conductive ball 21. The display medium layer 30 is disposed on the array substrate 10 and is surrounded by the sealant layer 20. The display medium layer 30 may include a display medium (such as liquid crystal), pixel electrodes, or a reflective layer and other components, but the present disclosure is not limited thereto.

The optical substrate 40 includes a solar conversion layer 41, an electrode conductive layer 42 and a first organic layer 43. The solar conversion layer 41 includes a positive electrode layer 411, a photoelectric conversion material layer 412 and a negative electrode layer 413 stacked in sequence. The positive electrode layer 411 is, for example, a transparent conductive layer. The negative electrode layer 413 is, for example, a metal film layer. The photoelectric conversion material layer 412 is, for example, a silicon-based semiconductor material layer. The solar cell unit is defined by the stacked positive electrode layer 411, the photoelectric conversion material layer 412, and the negative electrode layer 413. The solar conversion layer 41 is disposed on the second bezel area 220 of the display panel 1. The solar conversion layer 41 is not disposed on the display area 100 of the display panel 1. The electrode conductive layer 42 is disposed on the solar conversion layer 41 and is electrically connected to the solar conversion layer 41. The electrode conductive layer 42 is disposed on the second bezel area 220 of the display panel 1. The electrode conductive layer 42 is not disposed on the display area 100 of the display panel 1. In the embodiment, the electrode conductive layer 42 is electrically connected to the positive electrode layer 411 of the solar conversion layer 41. The electrode conductive layer 42 is, for example, a metal film layer. The first organic layer 43 is disposed on the electrode conductive layer 42 and covers the electrode conductive layer 42. In the embodiment, the first organic layer 43 located on the second bezel area 220 does not expose the electrode conductive layer 42. A vertical projection of the first organic layer 43 on the array substrate 10 and a vertical projection of the sealant layer 20 on the array substrate 10 overlap with each other. The optical substrate 40 further includes a second organic layer 44. The second organic layer 44 is disposed between the solar conversion layer 41 and the electrode conductive layer 42. The second organic layer 44 located on the second bezel area 220 exposes a portion of the positive electrode layer 411. The electrode conductive layer 42 is connected to the positive electrode layer 411 that is exposed by the second organic layer 44. In the embodiment, the optical substrate 40 further includes an upper electrode layer 45. The upper electrode layer 45 is disposed on the first organic layer 43. The upper electrode layer 45 is, for example, a transparent conductive layer. The upper electrode layer 45 located on the second bezel area 220 is in contact with the sealant layer 20. Thus, the sealant layer 20 may establish electrical connections with the electronic components of the optical substrate 40 through the upper electrode layer 45.

Please refer to FIG. 3. In the embodiment, the first bezel area 210 further includes a photoelectric conversion area 211 and a sealant area 212. In the embodiment, the solar conversion layer 41 is disposed on the first bezel area 210 of the display panel 1. The solar conversion layer 41 is not disposed on the display area 100 of the display panel 1. A solar cell unit is defined by the positive electrode layer 411 of the photoelectric conversion area 211, the photoelectric conversion material layer 412 and the negative electrode layer 413. In the embodiment, the electrode conductive layer 42 is disposed on the first bezel area 210 of the display panel 1, and the electrode conductive layer 42 is not disposed on the display area 100 of the display panel 1. In the embodiment, the electrode conductive layer 42 is electrically connected to the positive electrode layer 411 or the negative electrode layer 413 of the solar conversion layer 41. The electrode conductive layer 42 includes an electrode conductive layer 42a and an electrode conductive layer 42b. The electrode conductive layer 42a is electrically connected to the positive electrode layer 411 of the solar conversion layer 41 located on the photoelectric conversion area 211. The electrode conductive layer 42a is connected to the negative electrode layer 413 located on the sealant area 212 (212a). In the embodiment, the negative electrode layer 413 located on the sealant area 212a is used as a conductive layer. Therefore, an electrical property of the negative electrode layer 413 located on the sealant area 212a is the same as that of the electrode conductive layer 42a. The electrode conductive layer 42b is electrically connected to the negative electrode layer 413 of the solar conversion layer 41 located on the photoelectric conversion area 211. The electrode conductive layer 42b is connected to the negative electrode layer 413 located on the sealant area 212 (212b). In the embodiment, the negative electrode layer 413 located on the sealing area 212b is used as a conductive layer. Therefore, an electrical property of the negative electrode layer 413 located on the sealant area 212b is the same as that of the electrode conductive layer 42b.

In the embodiment, the first organic layer 43 is disposed on the electrode conductive layer 42 and only partially covers the electrode conductive layer 42. In this embodiment, the electrode conductive layer 42 is exposed by the first organic layer 43 located on the sealant area 212. A vertical projection of the first organic layer 43 on the array substrate 10 does not overlap with a vertical projection of the sealant layer 20 on the array substrate 10. The optical substrate 40 further includes a patterned organic layer 46. The patterned organic layer 46 is disposed on the electrode conductive layer 42 exposed by the first organic layer 43. The patterned organic layer 46 is located between the sealant layer 20 and the electrode conductive layer 42. The patterned organic layer 46 is only disposed on the sealant area 212. The patterned organic layer 46 exposes a portion of the electrode conductive layer 42. The patterned organic layer 46 and the first organic layer 43 are formed on the electrode conductive layer 42 through the same process.

The optical substrate 40 further includes a second organic layer 44. The second organic layer 44 is disposed between the solar conversion layer 41 and the electrode conductive layer 42. The second organic layer 44 located on the first bezel area 210 partially exposes the positive electrode layer 411 and the negative electrode layer 413. Thereby, the electrode conductive layer 42 may be electrically connected to the positive electrode layer 411 or the negative electrode layer 413 of the solar conversion layer 41. In the embodiment, the optical substrate 40 further includes an upper electrode layer 451 and an upper electrode layer 452. The upper electrode layer 451 is disposed on the patterned organic layer 46. The upper electrode layer 452 is disposed on the first organic layer 43. The upper electrode layer 451 is not electrically connected to the upper electrode layer 452. The upper electrode layer 451 and the upper electrode layer 452 have a distance along the first axis X. The upper electrode layers 451 and 452 are, for example, transparent conductive layers. The upper electrode layer 451 located on the first bezel area 210 is in contact with the sealant layer 20. Thereby, the sealant layer 20 may establish an electrical connection with the electrode conductive layer 42 (42a, 42b) through the upper electrode layer 451.

The present disclosure may effectively reduce the vertical distance between the lower electrode layer 15 and the upper electrode layer 451 by the disposition of a patterned organic layer 46 in the sealant area 212 of the first bezel area 210. That is, the gap (cell gap) of the sealant area 212 is reduced. Therefore, the sealant layer 20 located in the first bezel area 210 and the second bezel area 220 may have approximately equal heights H1 and H2 and widths W1 and W2. In one embodiment, the sealant layer 20 located in the first bezel area 210 and the second bezel area 220 have the same heights H1 and H2 and widths W1 and W2. That is, since the gap (cell gap) of the sealant area 212 is not larger than the second bezel area 220, the overall height H1 of the sealant layer 20 of the sealant area 212 located on the first bezel area 210 does not increase and does not have a narrow width W1. Thereby, the occurrence of uneven display in the display area 100 may be effectively reduced. Furthermore, because the width of the sealant layer 20 in the sealant area 212 is consistent, the conduction resistance caused by insufficient contact area of the sealant layer 20 may be avoided so that the solar cell may operate normally.

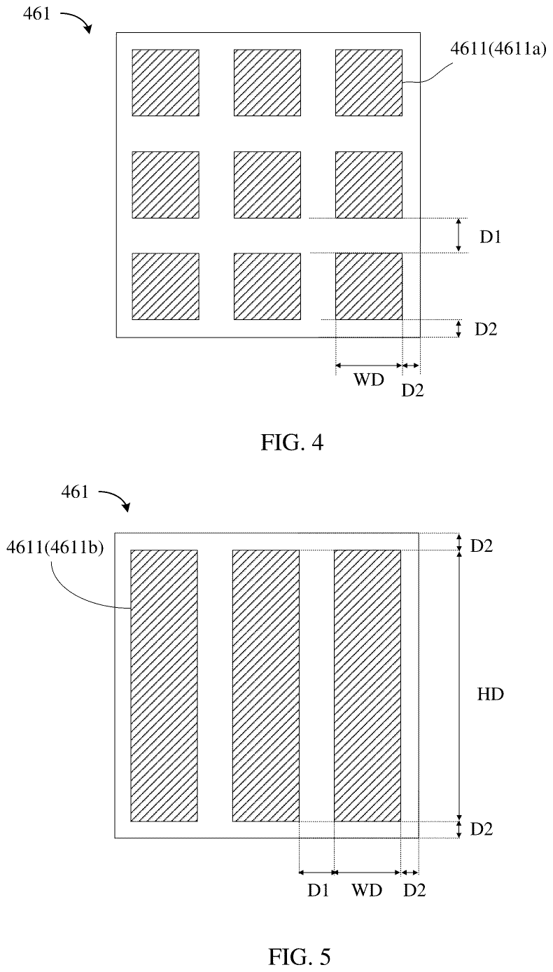

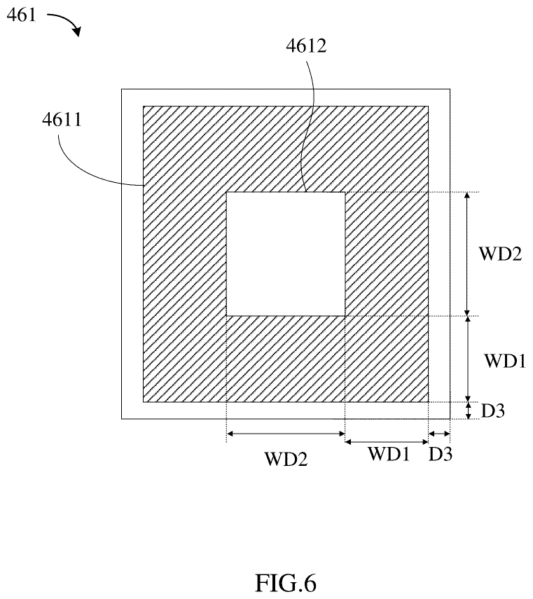

Please refer to FIG. 4 to FIG. 6. FIG. 4 to FIG. 6 are schematic diagrams of a pattern unit 461 of a patterned organic layer 46 under a unit area. The patterned organic layer 46 is implemented by at least one pattern unit 461. The pattern unit 461 includes a plurality of patterned units 4611. The patterned unit 4611 is a solid tetragon. A plurality of patterned units 4611 are arranged side by side within a unit area. The patterned unit 4611 has a width WD. The patterned units 4611 have a first distance D1 therebetween. At least one patterned unit 4611 has a second distance D2 from the edge of the pattern unit 461. In one embodiment, the solid tetragon is a square (as shown in FIG. 4). In one embodiment, the solid tetragon is a rectangle (as shown in FIG. 5). In one embodiment, the pattern unit 461 of the patterned organic layer 46 includes a patterned unit 4611. The patterned unit 4611 includes a hollow center area 4612. The center area 4612 is, for example, a rectangle. The patterned unit 4611 is a hollow rectangle (as shown in FIG. 6).

In one embodiment, a surface area of the pattern unit 461 of the patterned organic layer 46 is between 60% and 80% of a unit area. The surface area of the patterned organic layer 46 may be between 60% and 80% of the surface area of the sealant layer 20. Please refer to FIG. 4. In one embodiment, the unit area is 300 μm×300 μm (micrometers), and the patterned units 4611a are arranged in parallel with each other. The width WD of each patterned unit 4611a is 80 μm. The first distance D1 between the patterned units 4611a is 20 μm. The second distance D2 between the patterned unit 4611a and the edge of the unit area is 10 μm. In one embodiment, the unit area is 600 μm×600 μm, and the patterned units 4611a are arranged in parallel with each other. The width WD of each patterned unit 4611a is 160 μm. The first distance D1 between the patterned units 4611a is 40 μm. The second distance D2 between at least one patterned unit 4611a and the edge of the unit area is 20 μm. The surface area of the pattern unit 461 of the patterned organic layer 46 is 64% of the unit area. Please refer to FIG. 5. In one embodiment, the unit area is 300 μm×300 μm, and the patterned units 4611b are arranged in parallel with each other. The width WD of each patterned unit 4611b is 80 μm. The height HD of each patterned unit 4611b is 280 μm. The first distance D1 between the patterned units 4611b is 20 μm. The second distance D2 between a patterned unit 4611b and the edge of the unit area is 10 μm. In one embodiment, the unit area is 600 μm×600 μm, and the patterned units 4611b are arranged in parallel with each other. The width WD of each patterned unit 4611b is 160 μm. The height HD of each patterned unit 4611b is 560 μm. The first distance D1 between the patterned units 4611b is 40 μm. The second distance D2 between at least one patterned unit 4611b and the edge of the unit area is 20 μm. The surface area of the pattern unit 461 of the patterned organic layer 46 is 75% of the unit area. Please refer to FIG. 6. In one embodiment, the unit area is 300 μm×300 μm. The width WD1 of the patterned unit 4611 is 90 μm. A width WD2 of the region 4612 is 100 μm. A distance D3 between a patterned unit 4611 and the edge of the unit area is 10 μm. The surface area of the pattern unit 461 of the patterned organic layer 46 is 76% of the unit area.

According to the above, the present disclosure may effectively reduce the cell gap in the sealant area by disposing a patterned organic layer in the sealant area of the first bezel area of the display panel. Thus, the sealant layer located on the first bezel area and the sealant layer located on the second bezel area may have approximately the same height and width. The sealant layer located in the sealant area may not have an increased overall height or a narrower width because the gap in the sealant area is larger than the gap in the second bezel area. Therefore, the occurrence of uneven display around the display area may be effectively reduced. In addition, the on-resistance caused by insufficient contact area of the sealant layer may be avoided by keeping the sealant layer at the same width. Thus, the solar cell may operate normally.

It is to be understood that the term “comprises”, “comprising”, or any other variants thereof, is intended to encompass a non-exclusive inclusion, such that a process, method, article, or device of a series of elements not only includes those elements but also comprises other elements that are not explicitly listed, or elements that are inherent to such a process, method, article, or device. An element defined by the phrase “comprising a . . . ” does not exclude the presence of the same element in the process, method, article, or device that comprises the element.

Although the present invention has been explained in relation to its preferred embodiment, it does not intend to limit the present invention. It will be apparent to those skilled in the art having regard to this present invention that other modifications of the exemplary embodiments beyond those embodiments specifically described here may be made without departing from the spirit of the invention. Accordingly, such modifications are considered within the scope of the invention as limited solely by the appended claims.

What is claimed is:

1. A display panel including a display area and a bezel area surrounding the display
area including a plurality of first bezel areas extending along a second axis and a plurality of second bezel areas extending along a first axis perpendicular to the second axis comprising:
an array substrate;
a sealant layer, disposed on the array substrate, located on the first bezel areas and electrically connected to the array substrate; and
an optical substrate, disposed on the sealant layer and electrically connected to the sealant layer, comprising:
a solar conversion layer;
an electrode conductive layer, disposed on the solar conversion layer and electrically connected to the solar conversion layer and the sealant layer;
a patterned organic layer, disposed on the electrode conductive layer to expose a portion of the electrode conductive layer; and
an upper electrode layer, disposed on the patterned organic layer, located between the patterned organic layer and the sealant layer and electrically connected to the electrode conductive layer exposed by the patterned organic layer.

2. The display panel as claimed in claim 1, wherein a surface area of the patterned organic layer is between 60% and 80% of a surface area of the sealant layer.

3. The display panel as claimed in claim 1, wherein the patterned organic layer comprises a pattern unit, the pattern unit comprises a plurality of patterned units, the patterned units are solid tetragons, and the patterned units are arranged in parallel.

4. The display panel as claimed in claim 3, wherein the patterned units have a width, a first distance is between the patterned units, and a second distance is between an edge of the pattern unit and at least one of the patterned units.

5. The display panel as claimed in claim 4, wherein the width of the patterned units is 80 μm, the first distance is 20 μm, and the second distance is 10 μm.

6. The display panel as claimed in claim 4, wherein the width of the patterned units is 160 μm, the first distance is 40 μm, and the second distance is 20 μm.

7. The display panel as claimed in claim 1, wherein the patterned organic layer comprises a patterned unit and the patterned unit is a hollow rectangle.

8. The display panel as claimed in claim 7, wherein the patterned unit comprises a hollow center area, a width of the patterned unit is 90 μm, and a width of the center area of the patterned unit is 100 μm.

9. The display panel as claimed in claim 1, wherein the sealant layer located on the second bezel areas is electrically connected to the array substrate and is not electrically connected to the electrode conductive layer.

10. The display panel as claimed in claim 9, wherein a height of the sealant layer located on the first bezel areas is equal to a height of the sealant layer located on the second bezel areas.

11. The display panel as claimed in claim 9, wherein a width of the sealant layer located on the first bezel areas is equal to a width of the sealant layer located on the second bezel areas.

12. The display panel as claimed in claim 1, wherein the optical substrate comprises a first organic layer, the first organic layer is disposed on the electrode conductive layer, the first organic layer located on the first bezel areas exposes a portion of the electrode conductive layer, and a vertical projection of the first organic layer on the array substrate does not overlap with a vertical projection of the sealant layer on the array substrate.

13. The display panel as claimed in claim 1, wherein the optical substrate comprises a first organic layer in the second bezel areas, the first organic layer is disposed between the electrode conductive layer and the sealant layer, the first organic layer located on the second bezel areas covers the electrode conductive layer, and a vertical projection of the first organic layer on the array substrate overlaps with a vertical projection of the sealant layer on the array substrate.

14. The display panel as claimed in claim 1, wherein the electrode conductive layer is electrically connected to a positive electrode layer or a negative electrode layer of the solar conversion layer.
